(19) United States
(12) Patent Application Publication
(10) Pub. No.: US 2010/0052711 A1
(43) Pub. Date: Mar. 4, 2010

(54) PROBE CARD AND MANUFACTURING METHOD OF THE SAME

(75) Inventor: Ho Joon PARK, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/396,671

(22) Filed: Mar. 3, 2009

(30) Foreign Application Priority Data
Aug. 28, 2008 (KR) 10-2008-0084651

(51) Int. Cl. G01R 1/067; B32B 37/00

(52) U.S. Cl. 324/754; 156/230; 156/233

(57) ABSTRACT

There is provided a method of manufacturing a probe card, the method including: providing a first substrate including a plurality of probe pin patterns for forming a probe pin and at least one first stress relieving groove for relieving thermal stress; forming the probe pin by filling a metal material in the plurality of probe pin patterns; bonding a surface of the first substrate where the probe pin is formed onto a surface of a second substrate; and transferring the probe pin onto the second substrate by heating the first and second substrates bonded together.

### CROSS-REFERENCE TO RELATED APPLICATIONS

This application claims the priority of Korean Patent Application No. 2008-84651 filed on Aug. 28, 2008, in the Korean Intellectual Property Office, the disclosure of which is incorporated herein by reference.

### BACKGROUND OF THE INVENTION

1. Field of the Invention

The present invention relates to a probe card and a manufacturing method of the same, and more particularly, to a probe card capable of ensuring less damage to a probe pin and a manufacturing method of the same.

2. Description of the Related Art

A general semiconductor test device includes a tester, a performance board and a probe card and tests electrical properties of chips fabricated on a wafer. Also, the probe card of the semiconductor test device receives a signal generated from the tester through the performance board, transfers the signal to pads of the chip and transfers a signal outputted from the pads of the chip to the tester through the performance board.

To manufacture a conventional probe card, a probe pin is formed on a silicon substrate, and then the probe pin is bonded to a ceramic substrate. Specifically, a metal material is deposited or plated on the silicon substrate to form the probe pin. Also, the probe pin is bonded to a bump formed on the ceramic substrate. At this time, a temperature of about 300° C. is applied to perform eutectic bonding. In this process, the silicon substrate and the ceramic substrate suffer stress due to thermal expansion. This stress generated deforms the probe pin formed on the silicon substrate or alters a position of the probe pin. Moreover, the ceramic substrate also suffered stress which causes the probe pin not to be bonded at a precise position, thereby leading to bonding defects.

### SUMMARY OF THE INVENTION

An aspect of the present invention provides a manufacturing method of a probe substrate, in which a first substrate including at least one stress relieving groove for relieving thermal stress formed between a plurality of probe pins is employed to transfer the probe pins onto a second substrate, thereby ensuring less deformation of the probe pins.

An aspect of the present invention also provides a probe substrate including at least one stress relieving groove formed on a ceramic substrate where probe pins are bonded to relieve thermal stress to thereby enhance a bonding strength of the probe pins, and a manufacturing method of the same.

According to an aspect of the present invention, there including: providing a first substrate including a plurality of probe pin patterns for forming a probe pin and at least one first stress relieving groove for relieving thermal stress; forming the probe pin by filling a metal material in the plurality of probe pin patterns; bonding a surface of the first substrate where the probe pin is formed onto a surface of a second substrate; and transferring the probe pin onto the second substrate by heating the first and second substrates bonded together. The first substrate may be a silicon substrate.

The first stress relieving groove may be opened from a top to bottom of the first substrate. Also, the first stress relieving groove may include a plurality of stress relieving grooves. The plurality of first stress relieving grooves may be formed between the probe pin patterns on the first substrate.

The second substrate may be a ceramic substrate having a multilayer circuit structure. The second substrate may include at least one second stress relieving groove for relieving thermal stress. The second substrate may include a bonding metal layer formed on an area where the probe pin is to be transferred. The bonding metal layer may include at least one material selected from a group consisting of Au, Sn, Pb, Ni, Ag, Ti and a combination thereof.

According to another aspect of the present invention, there is provided a probe card including: a ceramic substrate including a stress relieving groove formed on a top thereof to relieve thermal stress; and a plurality of probe pins formed on the ceramic substrate, the plurality of probe pins each including a probe body part and a probe tip part. The stress relieving groove may be formed between the probe pins on the ceramic substrate.

The ceramic substrate may include a bonding metal layer for bonding the probe pins together. The bonding metal layer may include at least one material selected from a group consisting of Au, Sn, Pb, Ni, Ag, Ti and a combination thereof.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates a probe card according to an exemplary embodiment of the invention; and

FIGS. 2A to 2H illustrate a method of manufacturing a probe card according to an exemplary embodiment of the invention.

### DETAILED DESCRIPTION OF THE PREFERRED EMBODIMENT

Exemplary embodiments of the present invention will now be described in detail with reference to the accompanying drawings.

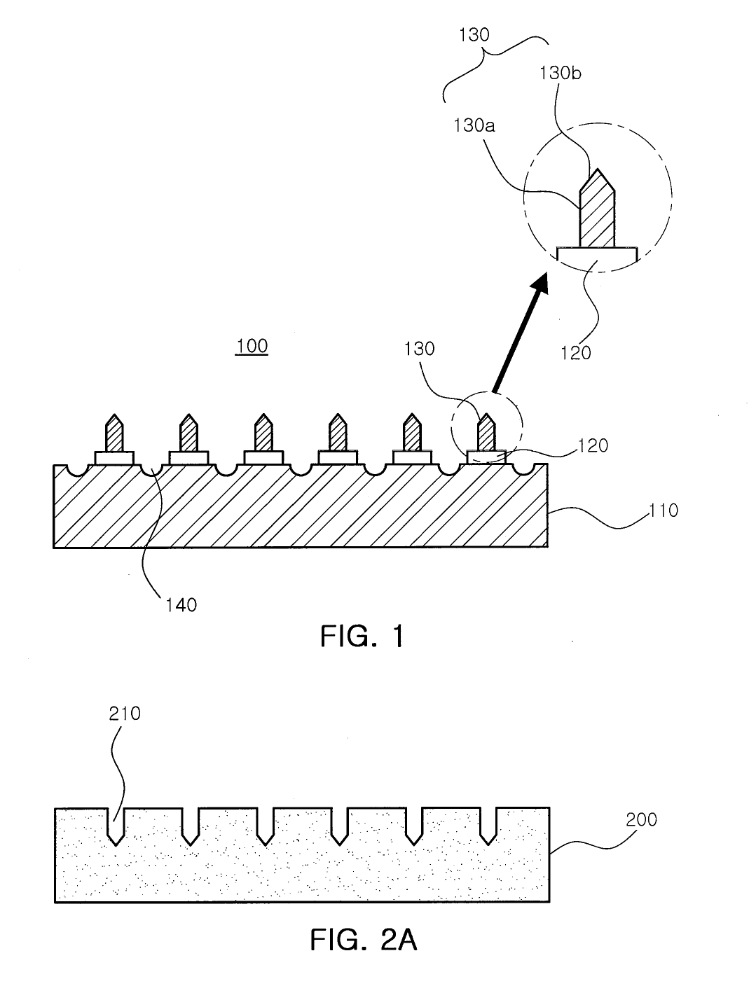

FIG. 1 illustrates a probe card according to an exemplary embodiment of the invention. Referring to FIG. 1, the probe card 100 includes a ceramic substrate 110, a bonding metal layer 120, a plurality of probe pins 130 and stress relieving grooves 140. Specifically, the ceramic substrate 110 includes a multilayer circuit structure (not shown) formed therein to be electrically connected to the probe pins 130 inside. Also, a test signal transmitted through the multilayer circuit is transferred to each of the probe pins 130 to measure electrical properties of an object of inspection.

The bonding metal layer 120 serves to bond the ceramic substrate 110 to the probe pin 130. Here, the bonding metal layer 120 may be formed of at least one material selected from a group consisting of Au, Sn, Pb, Ni, Ag, Ti and a combination thereof.

Referring to a magnified view of the probe pin 130, the probe pin 130 includes a probe body part 130a connected to the bonding metal layer 120 and a probe tip part 130b connected to a front end of the probe body part 130a. Here, the probe tip part 130b is in contact with the object of inspection such as a semiconductor chip and transfers the test signal, and receives a result signal from the object of inspection to measure electrical properties.

Meanwhile, the stress relieving grooves 140 formed on a top of the ceramic substrate 110 serve to relieve thermal 110. The ceramic substrate 110 has a thermal expansion coefficient of about 5.4 to 5.8 ppm/° C. and has a volume changed according to an increase in temperature. This change in volume generates stress in the ceramic substrate 110. The stress relieving grooves 140 absorb such a change in volume through an inner space thereof. Accordingly, this prevents the probe pins 130 from being detached from the ceramic substrate 110 or deformed. Therefore, each of the stress relieving grooves 140 may be formed between the plurality of probe pins 130.

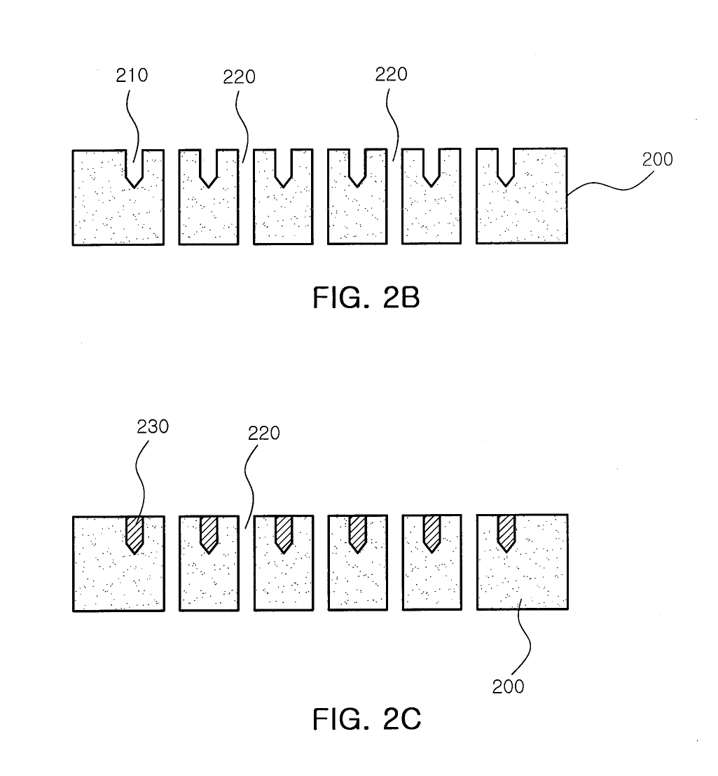

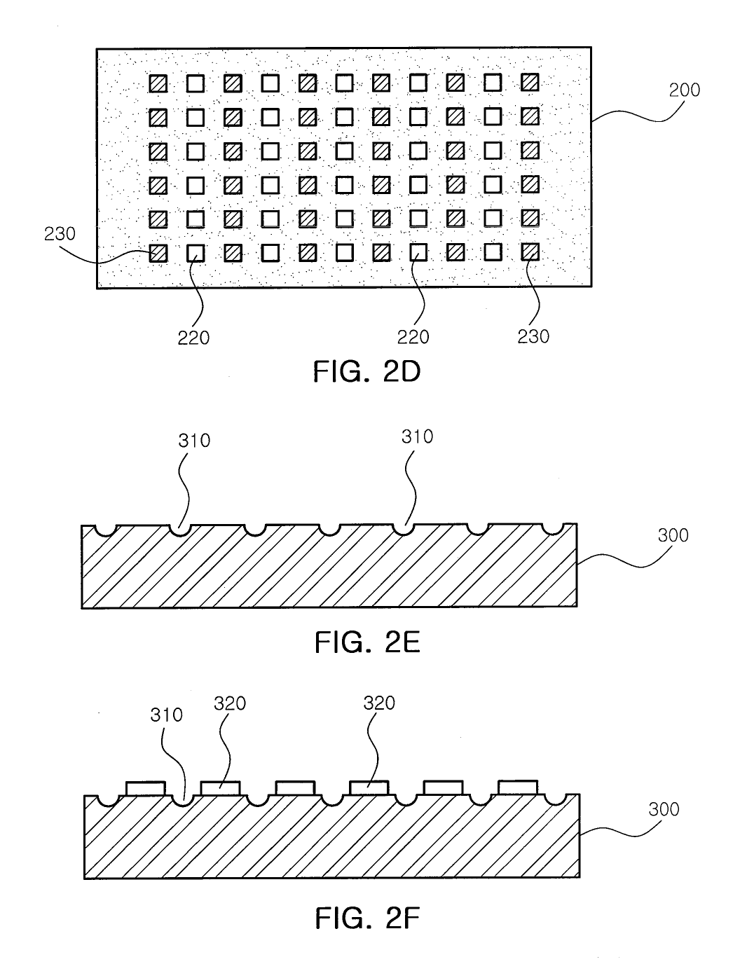

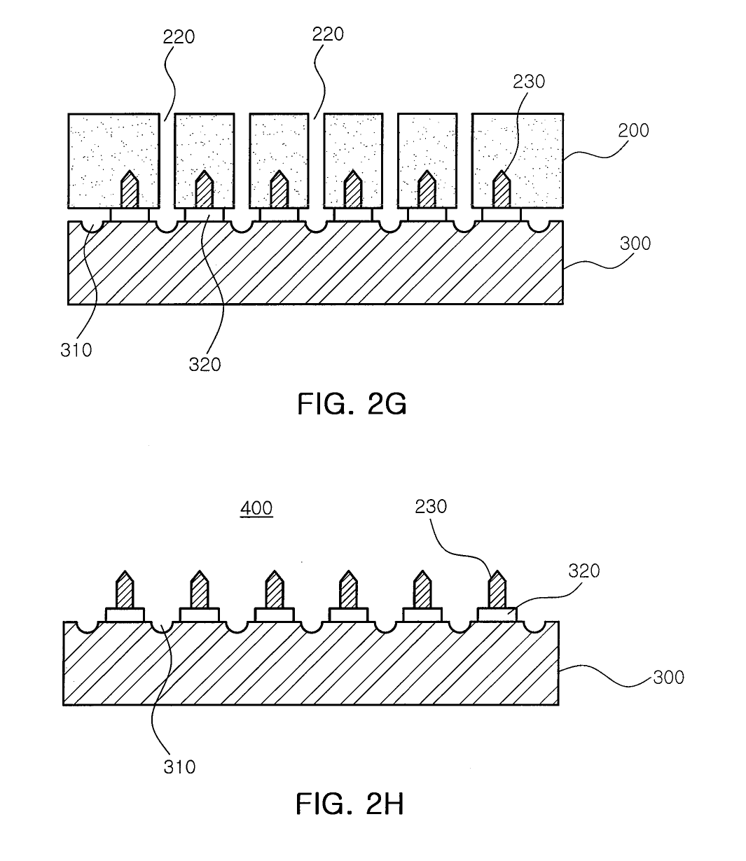

FIGS. 2A to 2H illustrate a method of manufacturing a probe card according to an exemplary embodiment of the invention. Referring to FIGS. 2A, a plurality of probe pin patterns 210 are formed on a first substrate 200 using photo lithography. These patterns 210 are employed to form the probe pins and may be shaped corresponding to the probe pins. Also, the first substrate 200 may utilize a silicon substrate.

Thereafter, as shown in FIG. 2B, an area of the first substrate 200 where the plurality of probe pin patterns 210 are not formed is etched to form first stress relieving grooves 220 between the probe pin patterns 210. Here, the first stress relieving grooves 220 may be extended to a predetermined depth of the first substrate 200. Alternatively, the first stress relieving grooves 220 may be configured as a through hole opened from a top to bottom of the first substrate 200. Moreover, the the first substrate 200 to have various shapes such as a triangle, a square and a circle.

Meanwhile, the first stress relieving grooves 220 formed in the top of the first substrate 200 relieve a thermal stress when a heat is applied to the first substrate 200. Specifically, the silicon substrate used as the first substrate 200 has a thermal expansion coefficient of 4.0 to 4.4 ppm/° C. and has a volume changed according to an increase in temperature. This change in volume generates a stress in the first substrate 200.

The first stress relieving grooves 220 relieve stress through an inner space thereof when a heat is applied to the first substrate 200. Here, the first stress relieving grooves 220 are configured as a through hole to ensure thermal stress is relieved more effectively through the inner space thereof.

Next, as shown in FIG. 2C, a metal material is filled in each of the probe pin patterns 210 to form probe pins 230. To fill the metal material, a conductor paste may be filled in the patterns or the metal material may be plated. Here, the metal material for forming the probe pins 230 may adopt Cu, Pt, Pa, Ni, Ag or Au.

FIG. 2D illustrates a top of the first substrate 200 shown in FIG. 2C. As shown in FIG. 2D, each of the plurality of stress relieving grooves 220 are formed between corresponding ones of the plurality of probe pins 230. Accordingly, an area of the first substrate 200 where the probe pins 230 are located suffers relatively less thermal stress, thereby preventing the probe pins 230 from being impaired or deformed.

Furthermore, referring to FIG. 2D, the stress relieving grooves 220 are positioned between the probe pins 230 arranged in a row to form a uniform arrangement. Also, the first stress relieving grooves 220 have an identical shape and size. However, the first stress relieving grooves 220 may be arranged irregularly and may have a different shape and size.

Afterwards, as shown in FIG. 2E, second stress relieving grooves 310 are formed on a second substrate 300. Here, the second substrate 300 may employ a ceramic substrate.

Moreover, the second stress relieving grooves 310 formed on the second substrate 300 serve to relieve thermal stress in the same manner as the first stress relieving grooves 220 of the first substrate 200.

Subsequently, as shown in FIG. 2F, bonding metal layers 320 are formed on the second substrate 300. The bonding metal layers 320 are an area onto which the probe pins 230 of the first substrate 200 are transferred when the first substrate 200 and the second substrate 300 are bonded together. Therefore, the bonding metal layers 320 may be formed at positions corresponding to the probe pins 230 formed on the first substrate 200. Here, the bonding metal layers 320 may include at least one material selected from a group consisting of Au, Sn, Pb, Ni, Ag, Ti and a combination thereof.

Thereafter, as shown in FIG. 2G, the first substrate 200 is bonded to the second substrate 300. Also, a heat of about 300° C. is applied to perform eutectic bonding in order to ensure that the probe pins 230 of the first substrate 200 are bonded to the bonding metal layers 320 of the second substrate. In this process, the first and second substrates 200 and 300 are changed in volume, respectively due to an increase in temperature. At this time, the first and second stress relieving grooves 220 and 310 formed in the first and second substrates 200 and 300, respectively absorb the changes in volume through inner spaces thereof to relieve thermal stress. This allows the probe pins 230 of the first substrate 200 to be transferred stably onto the bonding metal layers 320 of the second substrate 300.

As described above, the first and second stress relieving grooves 220 and 310 formed in the first and second substrates 200 and 200, respectively serve to reduce thermal stress. Accordingly, this prevents the probe pins 230 of the first substrate 200 and the bonding metal layers 320 of the second substrate 300 from being damaged or changed in position or configuration. Consequently this allows the probe pins 230 to be bonded at accurate positions without undergoing any damage, thereby producing a probe card 400 with higher reliability.

As set forth above, according to exemplary embodiments of the invention, a stress relieving groove is formed in at least one of first and second substrates to relieve thermal stress. The stress relieving groove serves to diffuse stress occurring due to a heat applied. Therefore, a probe pin formed on the first substrate, when transferred onto the second substrate, suffers less damage or deformation. Also, this increases a bonding strength of the probe pin and thus enhances reliability of a probe card.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a probe card, the method comprising:
providing a first substrate including a plurality of probe pin patterns for forming a probe pin and at least one first stress relieving groove for relieving thermal stress;
forming the probe pin by filling a metal material in the plurality of probe pin patterns;
bonding a surface of the first substrate where the probe pin is formed onto a surface of a second substrate; and
transferring the probe pin onto the second substrate by heating the first and second substrates bonded together.

2. The method of claim 1, wherein the first substrate is a silicon substrate.

3. The method of claim 1, wherein the first stress relieving groove is opened from a top to bottom of the first substrate.

4. The method of claim 1, wherein the first stress relieving groove comprises a plurality of stress relieving grooves.

5. The method of claim 4, wherein the plurality of first stress relieving grooves are formed between the probe pin patterns on the first substrate.

6. The method of claim 1, wherein the second substrate is a ceramic substrate having a multilayer circuit structure.

7. The method of claim 1, wherein the second substrate comprises at least one second stress relieving groove for relieving thermal stress.

8. The method of claim 1, wherein the second substrate comprises a bonding metal layer formed on an area where the probe pin is to be transferred.

9. The method of claim 8, wherein the bonding metal layer comprises at least one material selected from a group consisting of Au, Sn, Pb, Ni, Ag, Ti and a combination thereof.

10. A probe card comprising:
a ceramic substrate including a stress relieving groove formed on a top thereof to relieve thermal stress; and
a plurality of probe pins formed on the ceramic substrate, the plurality of probe pins each including a probe body part and a probe tip part.

11. The probe card of claim 10, wherein the stress relieving groove is formed between the probe pins on the ceramic substrate.

12. The probe card of claim 10, wherein the ceramic substrate comprises a bonding metal layer for bonding the probe pins together.

13. The probe card of claim 12, wherein the bonding metal layer comprises at least one material selected from a group consisting of Au, Sn, Pb, Ni, Ag, Ti and a combination thereof.
